(19) United States
(12) Patent Application Publication
(10) Pub. No.: US 2013/0154733 A1
(43) Pub. Date: Jun. 20, 2013

(54) METHOD FOR SYNTHESIZING SIGMA-DELTA MODULATOR

(71) Applicants: Shuenn-Yuh LEE, Chia-Yi (TW); Jia-Hua Hong, Keelung City (TW); Rong-Guey Chang, Chia-Yi (TW); Chih-Yuan Chen, Kaohsiung City (TW)

(72) Inventors: Shuenn-Yuh LEE, Chia-Yi (TW); Jia-Hua Hong, Keelung City (TW); Rong-Guey Chang, Chia-Yi (TW); Chih-Yuan Chen, Kaohsiung City (TW)

(21) Appl. No.: 13/325,547

(22) Filed: Dec. 14, 2011

(51) Int. Cl. H03F 1/26

(52) U.S. Cl. 330/149

(57) ABSTRACT

A method for synthesizing Sigma-Delta Modulator, which selects at least a system configuration and parameters, substitute a noise transfer formula into said system configuration to obtain coefficients. Using a least-square method to obtain a stability equation, and calculating an ideal performance of said system configuration based on said parameters and stability equation. Substitute the coefficients into non-ideal effect models, and acquire the circuit specification of an operation amplifier in said system configuration in a hierarchic approach to calculate the circuit performance of the operation amplifier. Determine whether said circuit specification of said operation amplifier has a solution based on related specification equation. If an answer is positive, calibrate length and width of transistors in said operation amplifier, until it meets the requirements of said circuit specification. Base on the said transistors to implement Sigma Delta Modulator, the target performance can be achieved from the circuit simulation result.

### BACKGROUND OF THE INVENTION

1. Field of the Invention

The present invention relates to a method for synthesizing Sigma-Delta Modulator, and in particular to a method for synthesizing Sigma-Delta Modulator, that is capable of integrating coefficient synthesis, circuit specification synthesis, and operation amplifier synthesis simultaneously in realizing the Sigma-Delta Modulator.

2. The Prior Arts

In recent years, Sigma-Delta modulators used in acoustic system have increased significantly, it can be found in various fields of applications ranging from the widely utilized MP3 to high level acoustic device, or even the hearing aid device. Since, presently, the electronic industry not only puts emphasis on high efficiency, but it also requires to reduce cost, therefore, how to rapidly and properly design a product meeting the user's requirements is an essential and important issue.

Presently, in the prior art, most of the technologies taking into account of only a single stage synthesis, have various problems and shortcomings. For example, in coefficient synthesis, the stability determination is not sufficiently accurate; in circuit specification synthesis, the performance obtained deviates too much from that of the real circuit; and the operation amplifier synthesis can be classified into three categories, wherein, the simulation-based synthesis takes too much time; the equation-based synthesis lacks accuracy; and the knowledge-based synthesis requires to establish an enormously large database, all these problems lead to the result that the system performance obtained deviates too much from that of the real circuit, also it takes too long to make such a synthesis.

Therefore, presently, the design and performance of method for synthesizing Sigma-Delta Modulator is not quite satisfactory, and it has much room for further improvements.

### SUMMARY OF THE INVENTION

In view of the problems and shortcomings of the prior art, the present invention provides a method for synthesizing Sigma-Delta Modulator, that is capable of shortening design schedule, and reducing system and circuit errors for the Sigma-Delta Modulator, hereby solving the drawbacks of the prior art.

A major objective of the present invention is to provide a method for synthesizing Sigma-Delta Modulator, that automatically perform synthesis for coefficients used in system configuration, operation amplifier circuit specification, and operation amplifier circuit.

Another objective of the present invention is to provide a method for synthesizing Sigma-Delta Modulator, which integrates non-ideal effect models of various circuits, to propose a simulation approach for predicting circuit performance more accurately.

A yet another objective of the present invention is to provide a method for synthesizing Sigma-Delta Modulator, that is capable of providing more accurate trans-conductance and drain-source conductance to generate a prediction model, for integrating related specification equations to obtain specifications of an operation amplifier, hereby synthesizing more rapidly and accurately operation amplifier meeting system requirements.

To achieve the objective mentioned above, the present invention provides a method for synthesizing Sigma-Delta Modulator, comprising following steps: (a) select at least a system configuration and a plurality of parameters, substitute a Noise Transfer Formula (NTF) into the system configuration to obtain a plurality of coefficients; then, use a least-square method to obtain a stability equation, and calculate an ideal peak-signal-to-noise-ratio (PSNR) and an ideal peak-signal-to-noise-distortion-ratio (PSNDR) of the system configuration based on the parameters and the stability equation; (b) substitute the coefficients into several circuit non-ideal effect models, and simulate specification of operation amplifier in the system configuration in a hierarchic approach, to calculate the predicted circuit performance of the operation amplifier; and (c) integrate equations of operation amplifier related specifications, utilize Geometric Programming (GP) algorithm to determine if the specification has a solution, and in case the answer is negative, then terminate the synthesis, otherwise, produce length and width of transistors in the operation amplifier, and make calibrations until the operation amplifier meet the requirements of the system specification.

Further scope of the applicability of the present invention will become apparent from the detailed description given hereinafter. However, it should be understood that the detailed description and specific examples, while indicating preferred embodiments of the present invention, are given by way of illustration only, since various changes and modifications within the spirit and scope of the present invention will become apparent to those skilled in the art from this detailed description.

### BRIEF DESCRIPTION OF THE DRAWINGS

The related drawings in connection with the detailed description of the present invention to be made later are described briefly as follows, in which:

FIG. 1 is a flowchart of the steps of a method for synthesizing Sigma-Delta Modulator according to the present invention;

FIG. 2 is a detailed flowchart of the steps S10 to S12 in FIG. 1;

FIG. 3 is a detailed flowchart of steps of operation amplifier synthesis of step S14 as shown in FIG. 1;

FIG. 4a is a circuit diagram of a fully differential folded-cascade operation amplifier according to the present invention;

FIG. 4b is a circuit diagram of the bias circuit used in FIG. 4a;

FIG. 5 is a circuit diagram of fully differential two-stage operation amplifier and a bias circuit;

FIG. 6a is a power spectrum density of Sigma-Delta Modulator utilizing fully differential folded-cascade operation amplifier according to the present invention; and

FIG. 6b is power spectrum density of Sigma-Delta Modulator utilizing fully differential two-stage operation amplifier according to the present invention.

### DETAILED DESCRIPTION OF THE PREFERRED EMBODIMENT

The purpose, construction, features, functions and advantages of the present invention can be appreciated and understood more thoroughly through the following detailed descriptions with reference to the attached drawings.

The present invention provides a method for synthesizing Sigma-Delta

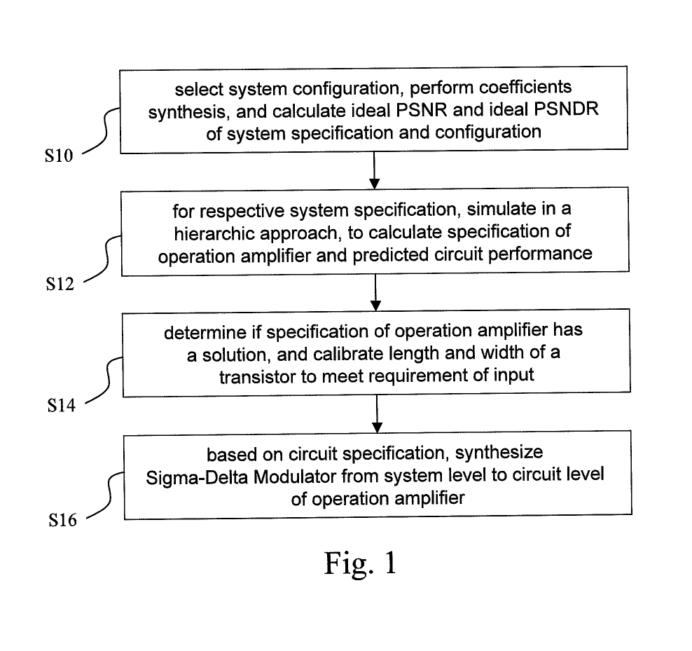

Modulator. Refer to FIG. 1 for a flowchart of the steps of a method for synthesizing Sigma-Delta Modulator according to the present invention, mainly comprising the following three steps. Firstly, execute step S10, synthesize system configuration coefficients, wherein, select a system configuration and a plurality of parameters; in general, the system configuration is a plural-number order Forward Feedback Sigma-Delta modulator (FF SDM), and the parameters include, order number, over-sampling factor, quantizer bit number, and maximum input amplitude, etc; substitute a high-pass filter equation (namely, noise transfer formula (NTF)) into the system configuration, to obtain various coefficients of the system configuration. Since in a fixed maximum input power, different performances can be obtained through increased attenuation quantity of noise transfer formula (NTF) in its bandwidth, so when attenuation quantity of noise transfer formula (NTF) in its bandwidth reaches a certain extent, system divergence could result. At this time, the Noise Power Gain (NPG) calculated using NTF is the maximum Noise Power Gain (NPGₘₐₓ) for the maximum input power. As such, through repeated simulations, to obtain the maximum Noise Power Gain (NPGₘₐₓ) corresponding to various maximum input powers. In step S10, upon collecting data about maximum Noise Power Gain, then utilize a least-square approach to obtain a stability equation, that approximates a third order equation; then, calculate and obtain an ideal peak-signal-to-noise-ratio (PSNR) and an ideal peak-signal-to-noise-distortion-ratio (PSNDR) of the system configuration through the parameters and the stability equation.

Next, proceed with step S12, to synthesize circuit specification, wherein, substitute coefficients into several non-ideal effect models of circuit, simulate specification of operation amplifier in this system configuration in a hierarchic approach; firstly, synthesize finite-gain and non-linearity of operation amplifier; then utilize the result thus obtained to combine with the non-ideal effect model of the operation amplifier bandwidth and the output voltage slew-rate to continue the synthesis, to calculate and obtain the bandwidth and slew-rate required; and finally, integrate the non-ideal effect model of clock jitter, to perform simulation of clock jitter, thus calculating to obtain the predicted circuit performance of the operation amplifier, and outputting specification of the operation amplifier and the predicted circuit performance.

Then, continue with step S14, synthesis of operation amplifier, and in this step establish a prediction model, that is realized through simulating various current and transistor width, to produce various trans-conductance (gₘ) and drain-source conductance (g_{ds}), collect the result of this trans-conductance (gₘ) and drain-source conductance (g_{ds}), and utilize length and width of a transistor and drain current as variables to establish a prediction model; then, integrate related specification equations of the operation amplifier, and this involves two synthesis approaches: equation-based synthesis and simulation-based synthesis, to determine if the specification of the operation amplifier has a solution, if the answer is negative, then terminate this process; otherwise, in the calibration stage, perform fine tune of transistor length and width of the operation amplifier based on results of synthesis, to achieve and output the optimal transistor length and width and circuit simulation results. Finally, in step S16, synthesize the Sigma-Delta modulator from the system level to the circuit level of the operation amplifier based on the circuit specification, to complete an automatic synthesis of the Sigma-Delta modulator.

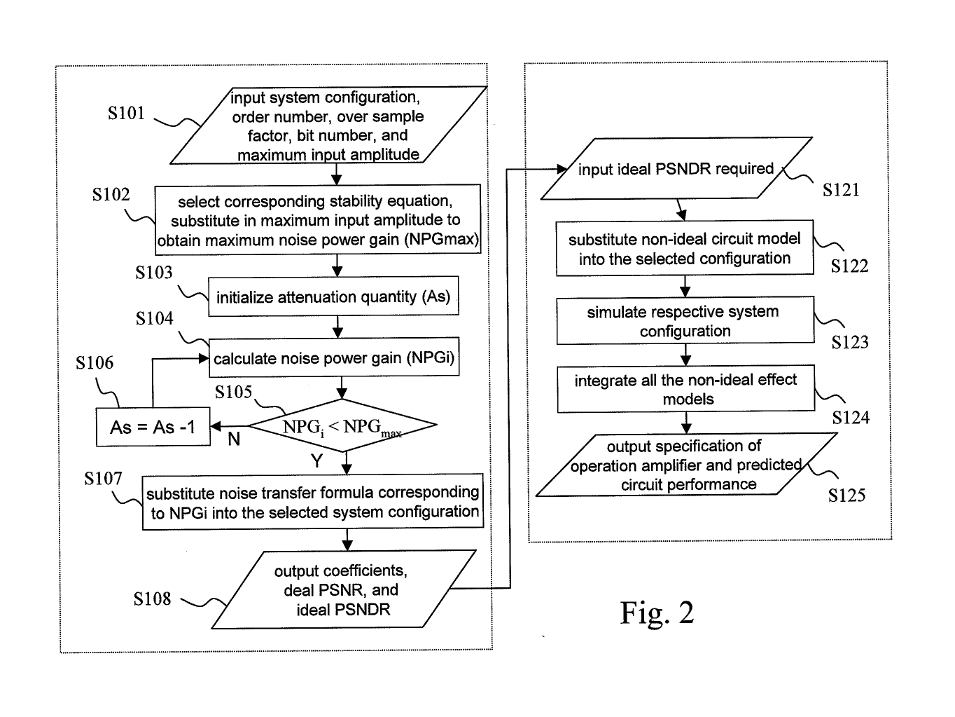

Then, refer to FIG. 2 for a detailed flowchart of the steps S10 to S12 in FIG. 1, wherein steps S101 to S108 relate to detailed steps of step S10; while steps S121 to S125 relate to the detailed steps of step S12. In step S101, input the system configuration, order number, oversampling factor, quantizer bit number, and maximum input (inputₘₐₓ (dB)) required. In step S102, select from database stability equation relative to various system configurations, order numbers, oversampling factors, and substitute it into maximum input amplitude (inputₘₐₓ), to obtain maximum Noise Power Gain (NPGₘₐₓ). In step S103, initialize the attenuation quantity (As) in bandwidth of operation amplifier. In step S104, calculate the Noise Power Gain (NPGᵢ) of Noise Transfer Formula (NTFᵢ) corresponding to the attenuation quantity. In step S105, determine if the noise power gain (NPGᵢ) is less than maximum noise power gain, if the answer is negative, then enter into step S106, decrement the attenuation quantity, and return to step S104 to recalculate noise power gain; otherwise, as shown in step S107, substitute the noise transfer formula corresponding to noise power gain into the system configuration. Finally, in step S108, output the coefficients of the system specification and configuration, ideal peak-signal-to-noise-ratio (PSNR), and the ideal peak-signal-to-noise-distortion-ratio (PSNDR).

Moreover, in step S121, input the ideal peak-signal-to-noise-distortion-ratio (PSNDR) required for predicting the circuit performance, and in step S122, substitute the coefficients generated in the previous stage into the non-ideal effect models. In step S123, perform simulations to the respective system specifications based on the proposed hierarchical simulation approach, including finite gain, nonlinearity, finite bandwidth and slew rate of operation amplifier, and clock jitter of operation amplifier. In step S124, integrate all the non-ideal effective models, and substitute them into circuit specification of operation amplifier, to proceed with simulation of performance prediction. In step 125, output the circuit specification of the operation amplifier and the predicted circuit performance.

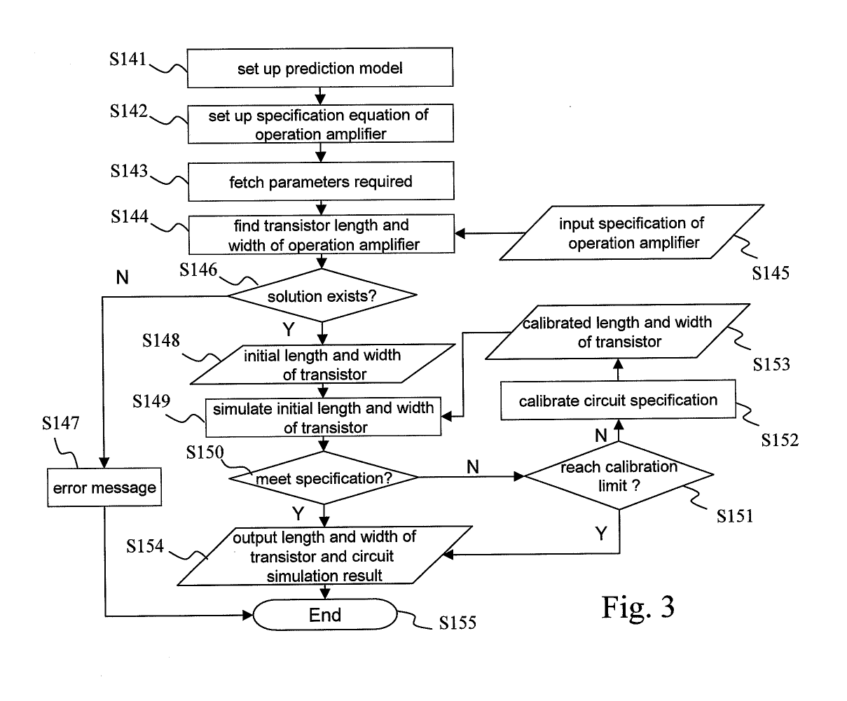

Subsequently, refer to FIG. 3 for a detailed flowchart of steps of operation amplifier synthesis of step S14 as shown in FIG. 1, wherein, it is classified as an initial synthesis stage and a calibration stage. Firstly, as shown in step S141, establish the trans-conductance (gₘ) and drain-source conductance (g_{ds}) as proposed by the present invention, and calculate the prediction model, that is the prediction model of the CMOS elements in the operation amplifier. In step S142, set up the specification equation of the operation amplifier. Then, in step S143, fetch the parameters required from the CMOS manufacturing process database. In step S144, utilize Geometric Programming (GP) algorithm to perform formula solution. In step S145, input circuit specification requirement, and this circuit specification is the operation amplifier circuit specification output by step S125 as shown in FIG. 2. The steps S142 to S144 mentioned above belong to the equation-based synthesis.

Then, as shown in step S146, determine if the width and length of transistors of the operation amplifier can be obtained through Geometric Programming (GP) algorithm based on the circuit specification, in case the answer is negative, then in step S147, output an error message and enter into step S155 to terminate the process; otherwise, as shown in step S148, generate the transistor's initial length and width of an operation amplifier, and in step S149, perform simulation based on the initial length and width of the transistor. In step S150, evaluate the result of simulation, namely whether the length and width of the transistor meet the circuit specification required, and if the answer is positive, then as shown in step S154, output the length and width of transistors and the result of simulation, and enter into step S155 and terminate the process; otherwise, enter into step S151 to determine if it has reached calibration limit, if the answer is positive, then in step S154 output the length and width of the transistor and the result of simulation, and enter into step S155 to terminate the process; otherwise, enter into step S152 to proceed with calibrations of various circuit specifications, and obtain relations between a plurality of transistor parameters based on a performance equation of the transistor, to proceed with fine tune of the transistor parameters, then enter into step S153 to obtain the calibrated length and width of the transistor, and return to step S149 to perform simulations on the calibrated length and width of the transistor. The steps S149 to S154 mentioned above belong to the simulation-based synthesis.

In the following, two design examples are provided for reference. In the table 1 below are the system specifications of Sigma-Delta modulators of the two design examples. Wherein, the first example select Feed-Forward (FF) configuration, with order number of 4, oversampling ratio (OSR) of 64, and bandwidth of 20 kHz, and it is realized through an operation amplifier of fully differential folded-cascode configuration. The second example utilizes Multiple-Feedback (MF) configuration, as shown in table 1 below, with order number of 3, oversampling ratio (OSR) of 32, and bandwidth of 256 kHz, and it is realized through an operation amplifier of fully differential two-stage configuration.

TABLE 1

| circuit specification | value | |
|---|---|---|
| system configuration | Feed-Forward (FF) | Multiple-Feedback (MF) |
| order number | 4 | 3 |
| Inputₘₐₓ (dB) | −6 | −6 |
| oversampling ratio | 64 | 32 |
| (OSR) | | |
| bandwidth (kHz) | 20 | 256 |
| configuration of | fully differential | fully differential |
| operation amplifier | folded-cascode | two-stage amplifier |
| | amplifier | |

Table 2 below is the coefficient synthesis and the result of ideal performance of the two exemplary system configurations as shown in Table 1.Wherein, a1-a4 are coefficients between integrators and quantizers for various stages in a Sigma-Delta Modulator system, b1-b2 are coefficients of partial feedback in a Sigma-Delta Modulator system, and g1-g4 are the gains of various stage integrators in the Sigma-Delta Modulator system.

TABLE 2

| | System configuration | |
|---|---|---|
| coefficient | Feed-Forward(FF) | Multiple-Feedback(MF) |
| a1 | 1.0056 | 1.1101 |
| a2 | 0.7430 | 1.3976 |
| a3 | 0.5702 | 1.0000 |
| a4 | 0.4490 | — |
| b1 | 0.0145 | 0.0484 |
| b2 | 0.0080 | — |
| g1 | 0.2350 | 0.2011 |
| g2 | 0.6022 | 0.2441 |
| g3 | 0.3184 | 0.6110 |
| g4 | 0.1382 | — |
| ideal PSNR (dB) | 104.70 | 63.08 |
| ideal PSNDR (dB) | 104.50 | 62.70 |
| required PSNDR (dB) | 93.00 | 61.00 |

The following Table 3 indicates the result of circuit specification synthesis, result of Geometric Programming (GP)(equation-based) prediction, simulation result of transistor size obtained through GP, and result of the present invention (integrating equation-based synthesis, simulation-based synthesis, and calibration).

TABLE 3

| | | | Target | | HSPICE | |
|---|---|---|---|---|---|---|
| System | | | OpAmp | GP | (before | present |
| config- | | | specifi- | Solu- | calibra- | inven- |
| uration | effect | | cation | tion | tion) | tion |
| Feed | clock | (ps) | ≦1,100 | — | — | — |
| Forward | jitter | | | | | |
| (FF) | OpAmp | (MHz) | ≧7.27 | 7.27 | 8.21 | 10.05 |
| | bandwidth | | | | | |
| | OpAmp | (V/μs) | ≧6.35 | 12.48 | 4.71 | 6.41 |
| | Slew rate | | | | | |
| | OpAmp | (dB) | ≧46.02 | 46.02 | 54.33 | 53.60 |
| | gain | | | | | |
| Multiple | clock | (ps) | ≦7,400 | | | |
| Feedback | jitter | | | | | |
| (MF) | OpAmp | (MHz) | ≧66.19 | 66.19 | 53.22 | 66.86 |
| | bandwidth | | | | | |
| | OpAmp | (V/μs) | ≧26.87 | 47.53 | 30.24 | 33.84 |
| | Slew rate | | | | | |
| | OpAmp | (dB) | ≧61.58 | 71.40 | 71.34 | 72.26 |
| | gain | | | | | |

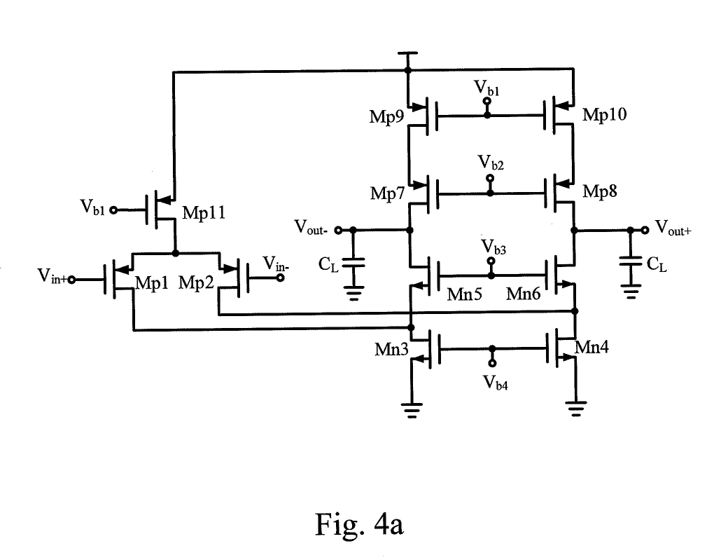

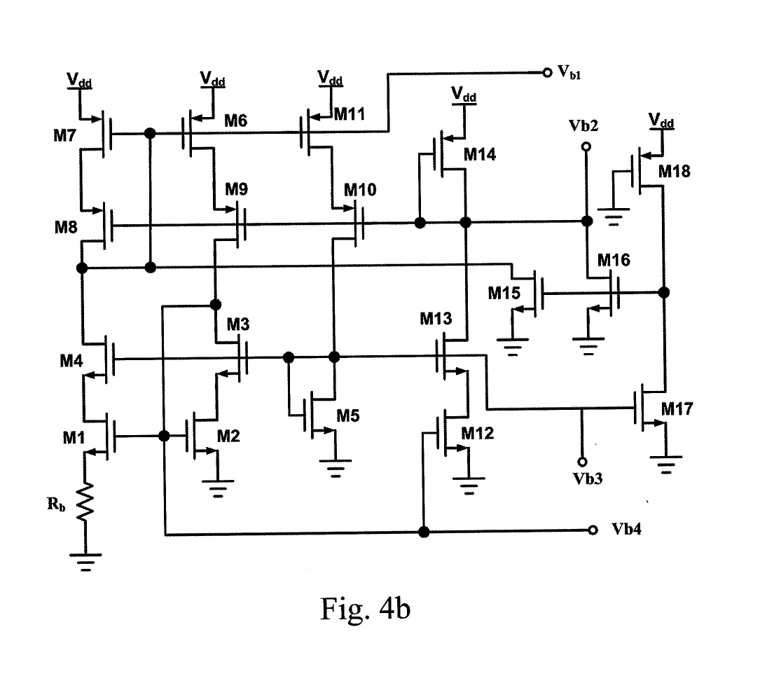

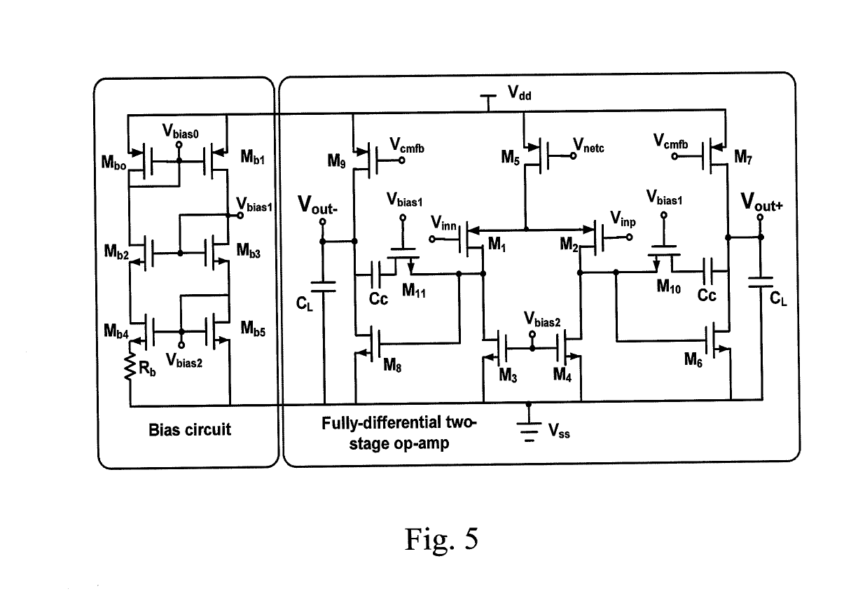

FIG. 4a is a circuit diagram of a fully differential folded-cascade operation amplifier according to the present invention, and FIG. 4b is a circuit diagram of the bias circuit used in FIG. 4a. FIG. 5 is a circuit diagram of fully differential two-stage operation amplifier and its bias circuit, wherein, the left half circuit is a common mode feedback circuit.

The following Table 4 indicates the transistor length and width of a fully differential folded-cascade operation amplifier, and ideal peak-signal-to-noise-distortion-ratio (PSNDR) of the Sigma-Delta Modulator system and the real circuit.

TABLE 4

| Parameter | unit | value | Parameter | value |
|---|---|---|---|---|
| Wₚ₁₋₂ | (μm) | 14.00 | W₁/L₁ | 3.45/1.00 |
| Wₙ₃₋₄ | (μm) | 1.70 | W_{2, 12}/L_{2, 12} | 0.865/1.00 |
| Wₙ₅₋₆ | (μm) | 16.40 | W_{3, 4,, 13}/L_{3, 4, 13} | 3.35/1.00 |
| Wₚ₇₋₈ | (μm) | 18.00 | W₅/L₅ | 1.00/1.00 |
| Wₚ₉₋₁₀ | (μm) | 4.45 | W_{6, 7, 11}/L_{6, 7, 11} | 5.50/1.00 |
| Wₚ₁₁ | (μm) | 8.90 | W_{8, 9, 10}/L_{8, 9, 10} | 2.45/1.00 |
| L | (μm) | 0.35 | W₁₄/L₁₄ | 1.40/2.00 |
| | (μm) | | W_{15, 16, 17}/L_{15, 16, 17} | 4.00/2.00 |
| | (μm) | | W₁₈/L₁₈ | 2.00/20.00 |
| Rb | (Ω) | 13.105 | | |
| ideal PSNDR | (dB) | 94.19 | PSNDR of | 93.03 |
| of system | | | real circuit | |

The following Table 5 indicates the transistor length and width of a fully differential two-stage operation amplifier, and ideal peak-signal-to-noise-distortion (PSNDR) of the Sigma-Delta Modulator system and a real circuit.

TABLE 5

| Parameter | unit | value | Parameter | value |
|---|---|---|---|---|
| W₁₋₂ | (μm) | 378.62 | W_{Mb0-1} | 6.30 |
| W₃₋₄ | (μm) | 100.03 | W_{Mb2-3} | 1.37 |
| W₅ | (μm) | 31.73 | W_{Mb4} | 157.30 |
| W₆, W₈ | (μm) | 198.14 | W_{Mb5} | 39.33 |
| W₇, W₉ | (μm) | 31.73 | | |
| W₁₀₋₁₁ | (μm) | 16.90 | | |
| Lₐₗₗ | (μm) | 0.7 | | |
| R_{b} | (Ω) | 1277.03 | | |
| C_{c} | (pF) | 3.85 | | |
| V_{netc} | (V) | 2.2922 | V_{cmfb} | 2.1305 |
| ideal PSNDR | (dB) | 59.52 | PSNDR of | 55.39 |
| of system | | | real circuit | |

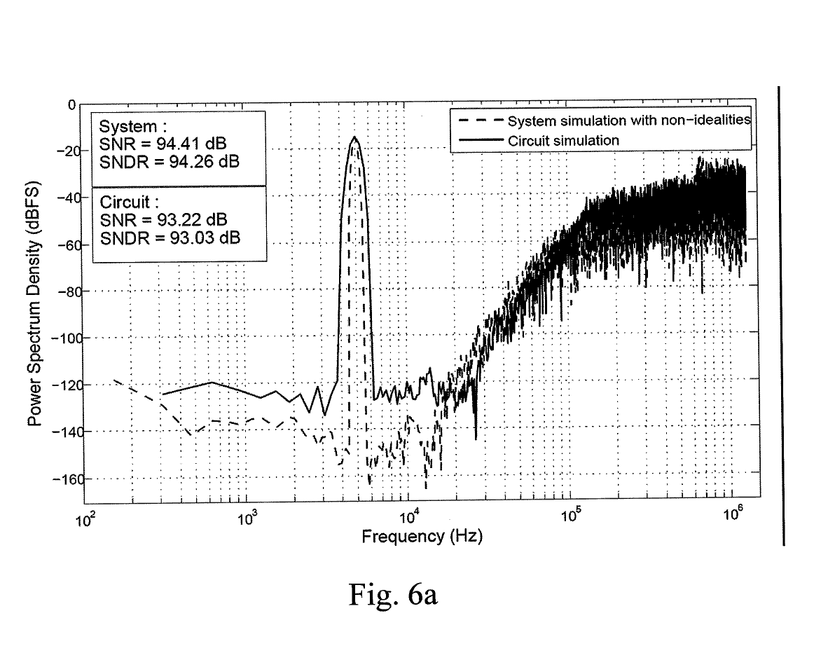

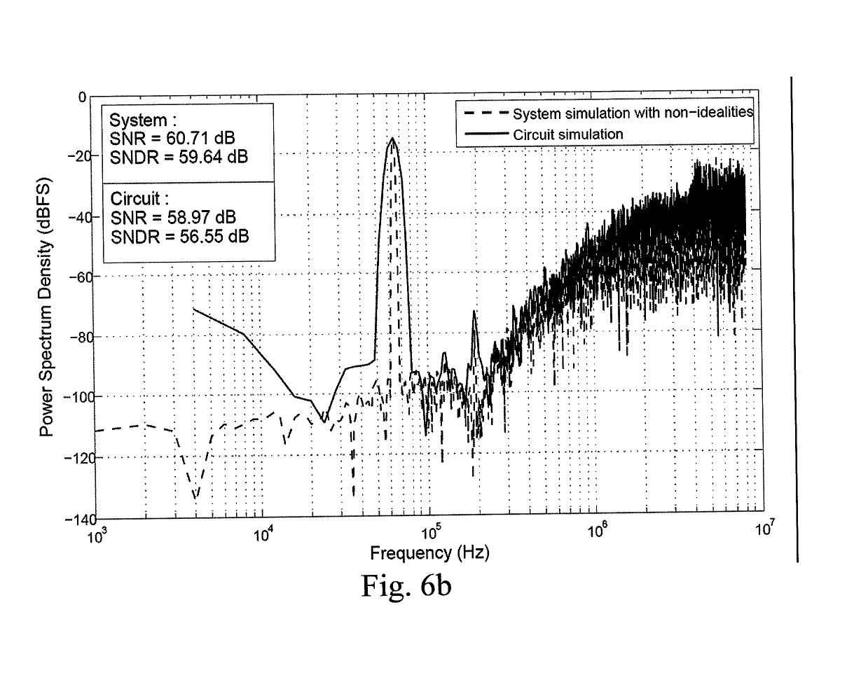

FIG. 6a is a power spectrum density of Sigma-Delta Modulator system utilizing fully differential folded-cascade operation amplifier according to the present invention; and FIG. 6b is power spectrum density of Sigma-Delta Modulator system utilizing fully differential two-stage operation amplifier according to the present invention.

Summing up the above, the present invention provides a method for synthesizing Sigma-Delta Modulator, that includes coefficient synthesis, circuit specification synthesis, and operational amplifier synthesis, and integrates these three parts into an automatic synthesis tool. Wherein, about the coefficient synthesis, the present invention proposes a new approach to determine the system stability of a Sigma-Delta Modulator, that is achieved through a third order equation of a least square method, which uses the maximum input power as input, and this equation takes into consideration of the variations in producing the switched-capacitor circuit, to increase the reliability of the equation; moreover, about the circuit specification synthesis, since the finite gain, nonlinearity, bandwidth, and slew rate of an operation amplifier are quite related to each other, so in the present invention, a new design approach is proposed, that can reduce significantly the performance difference between the system and the circuit; and furthermore, about the circuit synthesis of operation amplifier, the present invention proposes a new approach making use of trans-conductance (gₘ) and drain-source conductance (g_{ds}), meanwhile, it integrates equation-based and simulation-based syntheses, and it adds a calibration stage, so as to improve the inaccuracy of equation-based synthesis, and the defect of long time consuming of the simulation-based synthesis. Finally, the present invention proposes an automatic synthesis tool integrating the three kinds of syntheses mentioned above, and this automatic synthesis tool is capable of synthesizing rapidly from the system level to the operation amplifier circuit level based on user's input, as to save large amount of time used for design, so that even an inexperienced designer may readily and rapidly realize designing a Sigma-Delta Modulator.

The above detailed description of the preferred embodiment is intended to describe more clearly the characteristics and spirit of the present invention. However, the preferred embodiments disclosed above are not intended to be any restrictions to the scope of the present invention. Conversely, its purpose is to include the various changes and equivalent arrangements which are within the scope of the appended claims.

What is claimed is:

1. A method for synthesizing Sigma-Delta Modulator, comprising following steps:
(a) select at least a system configuration and a plurality of parameters, substitute a noise transfer formula into said system configuration to obtain a plurality of coefficients; then, use a least-square method to obtain a stability equation, and calculate an ideal peak-signal-to-noise-ratio (PSNR) and an ideal peak-signal-to-noise-distortion-ratio (PSNDR) of said system configuration based on said parameters and said stability equation;
(b) substitute said coefficients into at least a non-ideal effect model for simulating a circuit specification of an operation amplifier in said system configuration in a hierarchic approach, and calculate the predicted circuit performance of said operation amplifier; and
(c) integrate at least a specification equation related to said operation amplifier, to determine if said circuit specification of said operation amplifier has a solution, and in case the answer is negative, then terminate said synthesis, otherwise, calibrate length and width of at least a transistor in said operation amplifier, until width and length of said transistor meet the requirements of said circuit specification.

2. The method for synthesizing Sigma-Delta Modulator as claimed in claim 1, wherein said stability equation is a third order equation.

3. The method for synthesizing Sigma-Delta Modulator as claimed in claim 1, wherein said step (a) further comprising:
(a1) input said system configuration, an order number, an oversampling factor, a quantizer bit number, and a maximum input amplitude of said Sigma-Delta Modulator;
(a2) select from a database corresponding stability equation, substitute in said maximum input amplitude, to obtain a maximum Noise Power Gain (NPGₘₐₓ);
(a3) initialize an attenuation quantity in a bandwidth of said system configuration;
(a4) calculate a Noise Power Gain of a noise transfer formula (NTF) corresponding to said attenuation quantity; and
(a5) determine if said Noise Power Gain is less than said maximum Noise Power Gain (NPGₘₐₓ), if an answer is yes, reduce said attenuation quantity and return to step (a4), otherwise, substitute said noise transfer formula (NTF) corresponding to said Noise Power Gain into said system configuration, calculate and output said coefficients, said ideal peak-signal-to-noise-ratio (PSNR) and said ideal peak-signal-to-noise-distortion-ratio (PSNDR).

4. The method for synthesizing Sigma-Delta Modulator as claimed in claim 1, wherein said step (b) further comprising:
input said ideal peak-signal-to-noise-distortion-ratio (PSNDR);
input said coefficients into said non-ideal effect model, and substitute said non-ideal effect model into said system configuration;
perform hierarchic simulation for said system configuration;
integrate said non-ideal effect models, and substitute it into said circuit specification of said operation amplifier, and simulate predicted circuit performance of said operation amplifier; and
output said circuit specification and said predicted circuit performance of said operation amplifier,

5. The method for synthesizing Sigma-Delta Modulator as claimed in claim 1, wherein said step (c) further comprising:
set up a prediction model of said operation amplifier;
fetch from a database said parameters, and based on said specification equation to determine if said circuit specification of said operation amplifier has a solution;
in case an answer is positive, then use a geometric programming (GP) algorithm to find a solution for said specification equation, to obtain length and width of said transistor; and
simulate length and width of said transistor, to determine if they meet said circuit specification, and if answer is positive, then output length and width of said transistor, otherwise calibrate length and width of said transistor.

6. The method for synthesizing Sigma-Delta Modulator as claimed in claim 5, wherein said prediction model is set up through simulating different current and transistor width, to produce a trans-conductance and a drain-source conductance, then combining said transistor length and width and a drain current as a variable.

7. The method for synthesizing Sigma-Delta Modulator as claimed in claim 1, wherein calibrating length and width of said transistor further includes:
determine if calibrated length and width of said transistor reaches a calibration limit;
if answer is positive, then output said calibrated length and width of said transistor, otherwise continue calibrating said circuit specification; and
perform simulation of said calibrated length and width of said transistor, and determine again if said calibrated length and width of said transistor meets said circuit specification.

8. The method for synthesizing Sigma-Delta Modulator as claimed in claim 5, wherein calibrating length and width of said transistor further includes:
determine if said calibrated length and width of said transistor reaches a calibration limit;
if answer is positive, then output said calibrated length and width of said transistor, otherwise continue calibrating said circuit specification; and
perform simulation of said calibrated length and width of said transistor, and determine again if said calibrated length and width of said transistor meets said circuit specification.

9. The method for synthesizing Sigma-Delta Modulator as claimed in claim 1, further comprising: a step (d), said Sigma-Delta Modulator realizes automatic synthesis of said Sigma-Delta Modulator from system configuration level to circuit level of said operation amplifier as based on said circuit specification.

10. The method for synthesizing Sigma-Delta Modulator as claimed in claim 1, wherein said step (b) further includes: evaluate finite gain and nonlinearity of said operation amplifier, and add result of evaluation to a non-ideal bandwidth model and a non-ideal slew rate model, to calculate bandwidth and slew rate required by said operation amplifier.

11. The method for synthesizing Sigma-Delta Modulator as claimed in claim 1, wherein based on a performance equation, calibrate length and width of said transistor, to obtain relations between a plurality of transistor parameters, to perform fine-tune of said transistor parameters.
